(19) United States
(12) Patent Application Publication
(10) Pub. No.: US 2012/0074438 A1
(43) Pub. Date: Mar. 29, 2012

(54) METHOD FOR MANUFACTURING LIGHT EMITTING DEVICE, LIGHT EMITTING DEVICE, LIGHT EMITTING ELEMENT SUBSTRATE, AND QUALITY MANAGEMENT METHOD

(76) Inventors: Seong Deok HWANG, Seoul (KR); Young Hee Song, Seongnam (KR); Seong Jae Hong, Hwaseong (KR); Il Woo Park, Suwon (KR)

(21) Appl. No.: 13/243,496

(22) Filed: Sep. 23, 2011

(30) Foreign Application Priority Data
Sep. 28, 2010 (KR) 10-2010-0093892

(51) Int. Cl. H01L 33/08; H01L 21/66

(52) U.S. Cl. 257/88; 438/33; 438/15; 257/E21.531; 257/E33.064

(57) ABSTRACT

A method for manufacturing a light emitting device includes forming a plurality of light emitting elements on a light emitting element substrate. an identification portion is formed on each of the light emitting elements to allow a pertinent light emitting element to be distinguishable from other light emitting elements. The light emitting elements are separated to form a plurality of light emitting devices. The identification portion may have an external appearance allowing each of the light emitting elements to be distinguishable from the other light emitting elements.

### CROSS-REFERENCE TO RELATED APPLICATIONS

This application claims the priority of Korean Patent Application No. 10-2010-0093892 filed on Sep. 28, 2010, in the Korean Intellectual Property Office, the disclosure of which is incorporated herein by reference.

### BACKGROUND OF THE INVENTION

1. Field of the Invention

The present invention relates to a method for manufacturing a light emitting device, a light emitting device, a light emitting element substrate, and a quality management method.

2. Description of the Related Art

Conventional light emitting devices, such as a light emitting diode (LED), or the like, are manufactured by forming a plurality of light emitting elements on a wafer and then cutting a corresponding substrate by light emitting device. Each of the divided light emitting elements is disposed within a package including circuits according to purposes, a heat dissipation structure, and the like. Here, a technique of marking characteristic data of the light emitting elements disposed on a surface of the package has been known (e.g., Please refer to Patent Document 1).

### PRIOR ART DOCUMENT

### Patent Document

Patent Document 1: Japanese Laid Open Publication No. 2008-258584

### SUMMARY OF THE INVENTION

However, when the characteristic data of the light emitting elements is marked on the package, it may be difficult to manage by matching the characteristics of light emitting elements measured before being packaged as light emitting elements. Namely, since light emitting elements cannot be identified until such time as packaging is performed, it is difficult to identify which of several light emitting elements is a packaged light emitting element on the wafer. This makes it difficult to interpret a drawback in a process of manufacturing a wafer base, based on inspection results after packaging. Also, it is difficult to trace how the inspection results of a process of inspecting the wafer base affects product quality after packaging.

According to an aspect of the present invention, there is provided a method for manufacturing a light emitting device, including: an element formation operation of forming a plurality of light emitting elements on a light emitting element substrate; an identification portion formation operation of forming an identification portion on each of the light emitting elements to allow a pertinent light emitting element to be distinguishable from other light emitting elements; and a device formation operation of separating the light emitting elements to form a plurality of light emitting devices.

According to another aspect of the present invention, there is provided a light emitting device including: an element substrate; a light emitting element provided on the element substrate; and an identification portion allowing a pertinent light emitting element to be distinguishable from other light emitting elements.

According to another aspect of the present invention, there is provided a light emitting element substrate including a plurality of light emitting elements formed thereon, including: an identification portion allowing a pertinent light emitting element to be distinguishable from other light emitting elements.

According to another aspect of the present invention, there is provided a quality management method for managing the quality of a plurality of light emitting elements formed on a light emitting element substrate, including: a measurement operation of measuring the characteristics of each of the plurality of light emitting elements; and a result storing operation of identifying each of the plurality of light emitting elements and storing the measurement results of the characteristics of each of the plurality of light emitting elements, based on an identification portion of each of the plurality of light emitting elements.

The summary of the invention does not enumerate all of the essential characteristics of the present invention. Additionally, a sub-combination of the characteristic groups may constitute an invention.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a flow chart illustrating a process of a method for manufacturing a plurality of light emitting devices;

FIG. 2A shows an example of a light emitting element substrate 100 on which a plurality of light emitting elements are formed;

FIG. 2B shows an example of a certain reticle area 110;

FIG. 3 shows an example of an upper face of a light emitting element 10;

FIG. 4 is a cross-sectional view taken along line x-x′ of the light emitting element 10;

FIG. 5 is a cross-sectional view taken along line y-y′ of the light emitting element 10;

FIG. 6 is another example of an upper face of a light emitting element 10;

FIG. 7 is another example of an upper face of a light emitting element 10;

FIG. 8 is another example of an upper face of a light emitting element 10;

FIG. 9 is a perspective view of the light emitting element 10 illustrated in FIG. 8;

FIG. 10 shows another example of the upper face of the light emitting element 10;

FIG. 11 shows another example of the light emitting element 10;

FIG. 12A shows a pattern example of an identifying unit 17 formed on an elongated electrode unit 16b;

FIG. 12B shows a pattern example of an identifying unit 17 formed on an elongated electrode unit 16b;

FIG. 12C shows a pattern example of an identifying unit 17 formed on an elongated electrode unit 16b;

FIG. 13 is a flow chart illustrating a process of a method for manufacturing a light emitting device;

FIG. 14A shows an example of a light emitting element substrate 100;

FIG. 14B shows a substrate image corresponding to the light emitting element substrate 110;

FIG. 15 shows a configuration example of a lighting apparatus 700; and

FIG. 16 shows a configuration example of a backlight 800.

### DETAILED DESCRIPTION OF THE PREFERRED EMBODIMENT

The present invention will be described through embodiments, but the embodiments described hereinafter do not limit the invention regarding claim coverage. Also, all of the combinations of characteristics and features described in the embodiments are not essential for a solution of the invention.

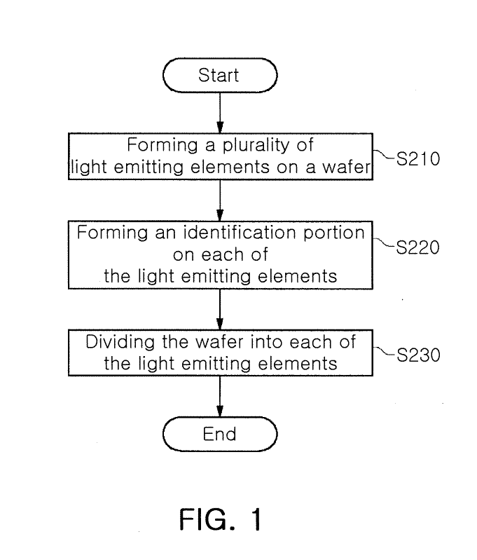

FIG. 1 is a flow chart illustrating a process of a method for manufacturing a plurality of light emitting devices. First, in an element formation operation S210, a plurality of light emitting elements are formed on a light emitting element substrate. After or during the element formation operation S210, a identification portion allowing for discriminating each light emitting element from other light emitting elements is formed on each of the light emitting units (identification portion formation operation (S220)). The identification portion may have an external appearance allowing for discriminating each light emitting element from other light emitting elements. In this case, the identification portion may be formed on a face, from which light is output, of a light emitting element. Thus, the identification portion may be discriminated even after a corresponding light emitting element is packaged.

The identification portion may have a two-dimensional mark, or may be formed by forming each semiconductor layer or an electrode in a different shape in each light emitting element. Also, information for discriminating a light emitting element may include at least one of a lot number of a light emitting element substrate, a wafer number within a lot, the position of a light emitting element on a light emitting element substrate, a serial number, a production date, and the like.

In a device formation operation S230, each of the light emitting elements is divided to form a plurality of light emitting devices. In the device formation operation S230, forming a lens with respect to each of the light emitting elements, applying phosphors, disposing each light emitting element in a package having certain circuits and a heat dissipation structure, and the like, may be additionally performed. After the identification portion is formed at each of the light emitting elements, the light emitting element substrate is divided into light emitting elements, so the light emitting elements can be identified even after the separation.

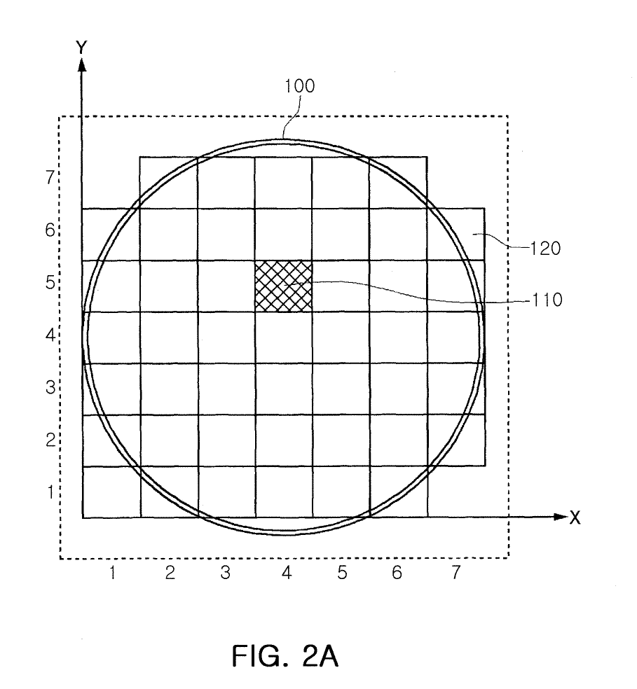

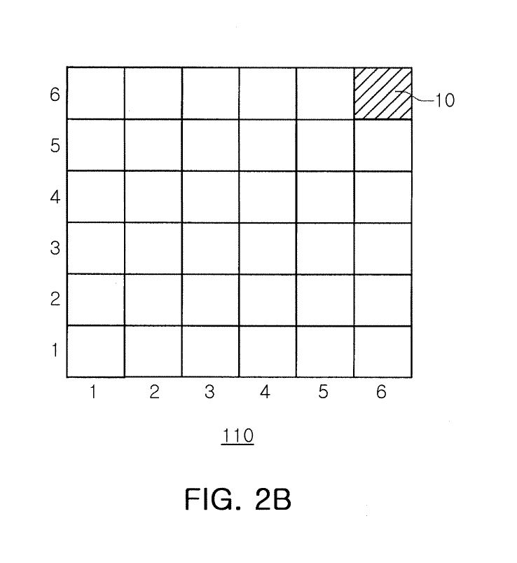

FIG. 2A shows an example of a light emitting element substrate 100 on which a plurality of light emitting elements are formed. The light emitting element substrate 100 may be a sapphire substrate or a semiconductor substrate. As shown in FIG. 2A, the light emitting element substrate 100 has a plurality of reticle areas 120. Each of the reticle areas 120 may be determined according to a range in which a pattern is irradiated through single exposure.

FIG. 2 shows an example of a certain reticle area 110. As shown in FIG. 2B, a plurality of light emitting elements 10 are formed in the reticle area 110. A identification portion, indicating a lot number of the light emitting element substrate 100, a number of the light emitting element substrate 100 within a lot, the position of the reticle area 110 in the light emitting element substrate 100, and the position of the light emitting element 10 in the reticle area 110, is formed in each of the light emitting elements 10. For example, in the case of the light emitting element 10 indicated as shaded in FIG. 2B, a identification portion indicating a lot number, the number of the light emitting element substrate 100, coordinates (x, y)=(4, 5) of the reticle area 110, and coordinates (x, y)=(6, 6) of the light emitting element 10 are provided.

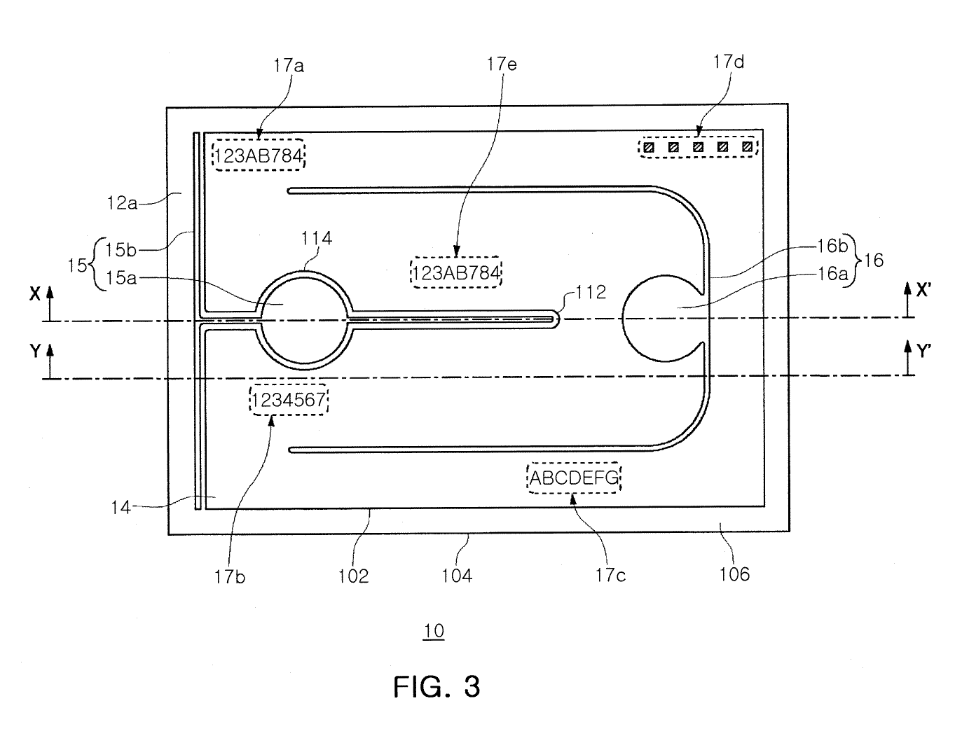

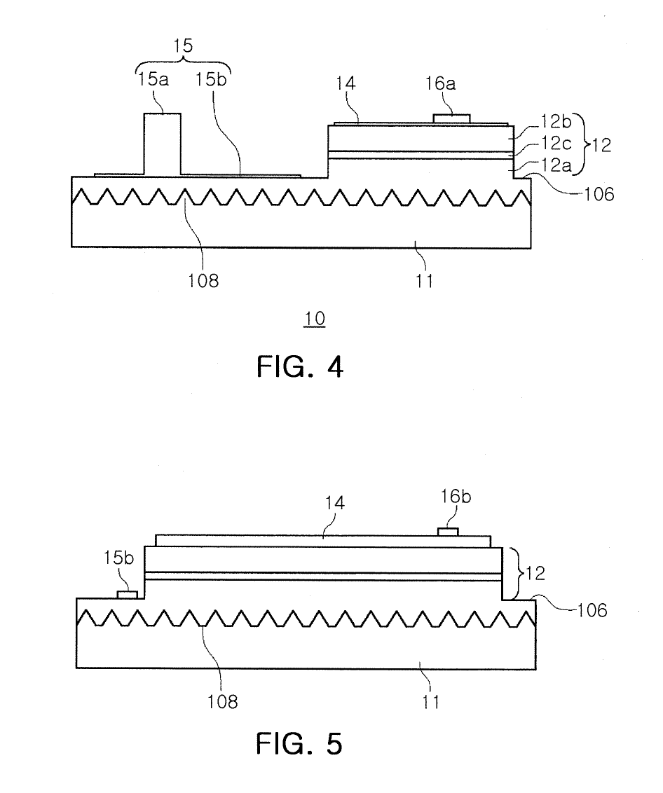

FIG. 3 shows an upper face of the light emitting element 10. FIG. 4 is a cross-sectional view taken along line x-x′ of the light emitting element 10. FIG. 5 is a cross-sectional view taken along line y-y′ of the light emitting element 10. The light emitting element 10 includes a light emitting element substrate 11, a semiconductor lamination unit 12, a transparent electrode 14, a first electrode unit 15, and a second electrode unit 16. The semiconductor lamination unit 12 is laminated on a surface of the light emitting element substrate 11. The light emitting element substrate 11 may be the same as the light emitting element substrate 100.

The semiconductor lamination unit 12 includes a first conductive type (e.g., n type) semiconductor layer 12a, a second conductive type (e.g., p type) semiconductor layer 12b, and a active layer 12c. The active layer 12c is formed between the semiconductor layer 12a and the semiconductor layer 12b and generates light according to the combination of electrons and holes injected from the both semiconductor layers. In the present embodiment, the semiconductor layer 12a, the active layer 12c, and the semiconductor layer 12b are laminated in order on the surface of the light emitting element substrate 11. Also, the transparent electrode 14 is formed over the entire surface of the semiconductor layer 12b.

An identification portion 17 is formed in the light emitting element 10. The identification portion 17 denotes information regarding a manufacturing process in a wafer base. The information denoted by the identification portion 17 may be at least one of a lot number of the light emitting element substrate 100, a wafer number in a lot, the position of the light emitting element 10 in the light emitting element substrate 100, a serial number, a production date, and the like. With an external appearance according to the corresponding information, the identification portion 17 discriminates each light emitting element 10 from other light emitting elements 10.

The light emitting element 10 according to the present embodiment has the identification portion 17 on the transparent electrode 14. Information contained within the identification portion 17 may be in the form of a character, a symbol, a figure, or the like, formed on the transparent electrode 14 through laser machining, or the like. A figure may be arrayed with regularity or periodicity, like a barcode, and information is represented according to the array pattern. Also, the light emitting element 10 may have a plurality of identification portions 17 on the transparent electrode 14. Also, the identification portion 17 may be formed by changing a portion of a mask used in a manufacturing process of the light emitting element 10 for every light emitting element.

The light emitting element 10 may have a plurality of identification portions 17 having the same external appearance, like identification portions 17a and 17e. Also, the light emitting element 10 may have a plurality of identification portions 17 each having a different external appearance, like identification portions 17a, 17b, 17c, and 17d. A disposition area of the identification portion 17 is previously determined according to the type of denoted information.

The light emitting element 10 may have an identification portion 17 formed in the vicinity of the respective corners of the transparent electrode 14. Also, the light emitting element 10 may have the identification portion 17 provided on one of shorter sides of the transparent electrode 14, where an elongated electrode unit 15b is formed, like the identification portion 17a, or may have the identification portion 17 at the other shorter sides of the transparent electrode 14 where the elongated electrode unit 15b is not formed.

Also, the light emitting unit 10 may have the identification portion 17 provided between the elongated electrode unit 15b and an elongated electrode unit 16b which are stretched in parallel, like the identification portion 17e. Also, the light emitting element 10 may have the identification portion 17 provided between the electrode pad 15a and the elongated electrode unit 16b, like the identification portion 17b.

Also, the light emitting unit 10 may have the identification portion 17 provided between a longer side of the transparent electrode 14 and the elongated electrode unit 16b, like the identification portion 17c. Also, the light emitting element 10 may have the identification portion 17 provided at positions which are at the maximum distance from the first and second electrodes 15 and 16 on the transparent electrode 14.

The identification portion 17 may not be limited to those whose external appearance can be distinguishable by the naked eye. An external appearance of the identification portion 17 may be distinguished by using an observation instrument such as a microscope, or the like. Also, the identification portion 17 may be formed on the surface of the semiconductor layer 12b.

The transparent electrode 14 may be formed to cover the identification portion 17 formed on the surface of the semiconductor layer 12b. Namely, the identification portion 17 may be formed on the surface of the semiconductor layer 12b covered by the transparent electrode 14. In this case, the identification portion 17 is formed on the semiconductor layer 12b, and then, the transparent electrode 14 is formed on the semiconductor layer 12b. Accordingly, the external appearance of the identification portion 17 may be monitored from the outside and the identification portion 17 can be protected.

The transparent electrode 14, the semiconductor layer 12b, and the active layer 12c are mesa-etched along the outer circumference of the light emitting element 10. In concert with this, a portion of the semiconductor layer 12a may also be etched along the outer circumference of the light emitting element 10. Accordingly, a scribed area 106 is formed on the outer circumference of the light emitting element 10, allowing the light emitting element substrate 11 to be easily cut when the light emitting element 10 is separated. Also, the scribed area 106 may serve as an exposure area from which the surface of the semiconductor layer 12a is exposed to allow an electrode, or the like, to be formed.

In FIG. 3, a boundary line 102 indicates the position of a side formed through mesa-etching. Also, a boundary line 104 indicates the boundary between light emitting elements 10 when the light emitting elements 10 are individually divided. As shown in FIG. 3, even after the light emitting elements 10 are individually divided, a portion of the scribed area 106 remains in each of the light emitting element 10.

The scribed area 106 is formed to have a regular width along the outer circumference of the light emitting element 10. The outer circumference of the light emitting element 10 may have a rectangular shape. The width of the scribed area 106 is a width of the light emitting element 10 in a direction perpendicular to an outer circumferential line. Here, the width of the scribed area 106 at one shorter side in the outer circumference of the light emitting element 10 may be larger than the width of the scribed area 106 of a different area. At least a portion of the first electrode 15 may be formed on the surface of the semiconductor layer 12a exposed by the scribed area 106 having a relatively large width.

The first electrode unit 15 is electrically connected to the semiconductor layer 12a. In the present embodiment, the first electrode unit 15 is formed on the surface of the semiconductor layer 12 exposed as the transparent electrode 14, the semiconductor layer 12b, and the active layer 12c are removed. The first electrode unit 15 includes the electrode pad 15a and the elongated electrode unit 15b.

The electrode pad 15a is electrically connected to an outer electrode or a wire. The electrode pad 15a may have, for example, a circular section. The elongated electrode unit 15b has a width smaller than that of the electrode pad 15a. The width of the electrode pad 15a may indicate a diameter of the electrode pad 15a. The width of the elongated electrode unit 15b may indicate the shortest length traversing the elongated electrode unit 15b. The elongated electrode unit 15b may be stretched from the electrode pad 15a.

As mentioned above, at least portions of the electrode pad 15a and the elongated electrode unit 15b are formed at the scribed area 106 formed at one shorter side of the light emitting unit 10. Also, as shown in FIGS. 3 and 4, a stretched area 112 may be formed through etching at the transparent electrode 14, the semiconductor layer 12b, and the active layer 12c.

The stretched area 112 is formed to be stretched toward the center of the transparent electrode 14, or the like, from the scribed area 106 where a portion of the first electrode 15 is formed. The transparent electrode 14, the semiconductor layer 12b, and the active layer 12c are removed from the stretched area 112. A lower surface of the stretched area 112 may be coplanar with the scribed area 106.

In the present embodiment, the stretched area 112 is formed to be stretched from the center of the scribed area 106 at the shorter side in which at least a portion of the first electrode 15 is formed toward an inner side of the transparent electrode 14, or the like. The width of the stretched area 112 may be smaller than any portion of the scribed area 106. As shown in FIGS. 3 and 4, at least a portion of the elongated electrode unit 15b may be formed on the stretched area 112.

The stretched area 112 has an expanded area 114 having a section according to an external appearance of the electrode pad 15a. The expanded area 114 may have, for example, a circular section. The width of the expanded area 114 may be larger than that of the stretched area 112. The width of the expanded area 114 is, for example, the diameter of the section. Also, the width of the expanded area 114 may be larger than any portion of the scribed area 106. The electrode pad 15a is formed on the expanded area 114.

The stretched area 112 may have a linear shape. Also, the stretched area 112 may be formed extendedly to be longer than half of the longer side of the transparent electrode 14. Namely, the stretched area 112 may be stretched beyond the center of the transparent electrode 14. Also, the expanded area 14 may be formed to be close to an end portion of the transparent electrode 14, rather than to the center of the stretched area 112, in the stretched direction of the stretched area 112.

The second electrode 16 is electrically connected to the semiconductor layer 12b. In the present embodiment, the second electrode 16 is formed on the transparent electrode 14 and electrically connected to the semiconductor layer 12b through the transparent electrode 14. The second electrode 16 includes an electrode pad 16a and the elongated electrode unit 16b.

The electrode pad 16a is provided at a position opposed to the electrode pad 15a. In detail, the electrode pad 16a is disposed substantially at the center in the direction of the shorter side of the transparent electrode 14 and provided at the opposite side of the electrode pad 15a based on the center of the transparent electrode 14 in the direction of the longer side of the transparent electrode 14. The electrode pad 16a is disposed to be separated from any sides of the transparent electrode 14.

The elongated electrode unit 16b has a width smaller than that of the electrode pad 16a. The elongated electrode unit 16b is stretched from the electrode pad 16a. In the present embodiment, the elongated electrode unit 16b is stretched from an area closest to the opposed shorter side of the electrode pad 16a along the shorter side. The elongated electrode unit 16b may be stretched from the electrode pad 16a toward both sides in the direction of the shorter side.

Also, the elongated electrode unit 16b may be stretched along the shorter side of the transparent electrode 14 and then further stretched along the longer side of the transparent electrode 14. The portion of the elongated electrode unit 16b stretched along the longer side of the transparent electrode 14 is separated by a certain distance from the corresponding longer side. The distance between the elongated electrode unit 16b and the corresponding longer side may be substantially equal to the distance between the elongated electrode unit 16b and the shorter side of the transparent electrode 14. The portion of the elongated electrode unit 16b parallel to the longer side of the transparent electrode 14 may be stretched up to a position opposed to the electrode pad 15a.

Also, a portion connecting the portion of the elongated electrode unit 16b parallel to the shorter side of the transparent electrode 14 and the portion of the elongated electrode unit 16b parallel to the longer side of the transparent electrode 14 may be formed as a curved line. Such a configuration can prevent current from being concentrated in a certain area.

The elongated electrode unit 16b has a pattern such that the distance from respective points of the electrode pad 15a and the elongated electrode unit 15b to the closest point of the second electrode is within a predetermined distance. The predetermined distance may be smaller than half of the shorter side of the transparent electrode 14. Also, the predetermined distance may be double the distance between the elongated electrode unit 16b and the shorter side of the transparent electrode 14. By setting the distance between the first electrode unit 15 and the second electrode unit 16 to be within the predetermined range, uniformity of current diffusion can be improved.

Also, as shown in FIG. 4, the height of the elongated electrode unit 15b is lower than the interface between the active layer 12c and the semiconductor layer 12a. Namely, in the scribed area 106 and the stretched area 112, the surface portion of the semiconductor layer 12a is removed to be higher than the height of the elongated electrode unit 15b. Accordingly, the elongated electrode unit 15b can be prevented from being connected to the active layer 12c and the semiconductor layer 12a.

The height of the electrode pad 15a may be substantially equal to that of the electrode pad 16a of the second electrode 16. Namely, the electrode pad 15a may be exposed from the surface of the electrode pad 14. In this case, an insulating material may be formed between the electrode pad 15a and the semiconductor layer 12b (or the transparent electrode 14).

For example, after the elongated electrode unit 15b is formed on the stretched area 112, the expanded area 114 is formed to penetrate the active layer 12c, the semiconductor layer 12b, and the transparent electrode 14. Then, an insulating material is formed on a wall face of the expanded area 114. Here, the insulating material may also be formed on a wall face of the stretched area 112. Thereafter, the interior of the expanded area 114 is filled with a conductive material. With this configuration, the electrode 15a and the electrode pad 16a can be exposed from the same surface of the light emitting element 10.

Also, the height of the electrode pad 15a may be lower than the interface between the active layer 12c and the semiconductor layer 12a. Also, the height of the electrode pad 15a may be higher than the elongated electrode unit 15b. In this case, an insulating material may not be formed between the electrode pad 15a and the semiconductor layer 12b (or the transparent electrode 14).

Also, the light emitting element substrate 11 may have a concavo-convex pattern (or a depression and protrusion pattern) on the entire surface 108 on which the semiconductor layer 12a is laminated. Accordingly, light extraction efficiency can be improved. The light emitting element 10 may emit light from the side opposed to the side on which the first electrode 15 and the second electrode 16 are formed.

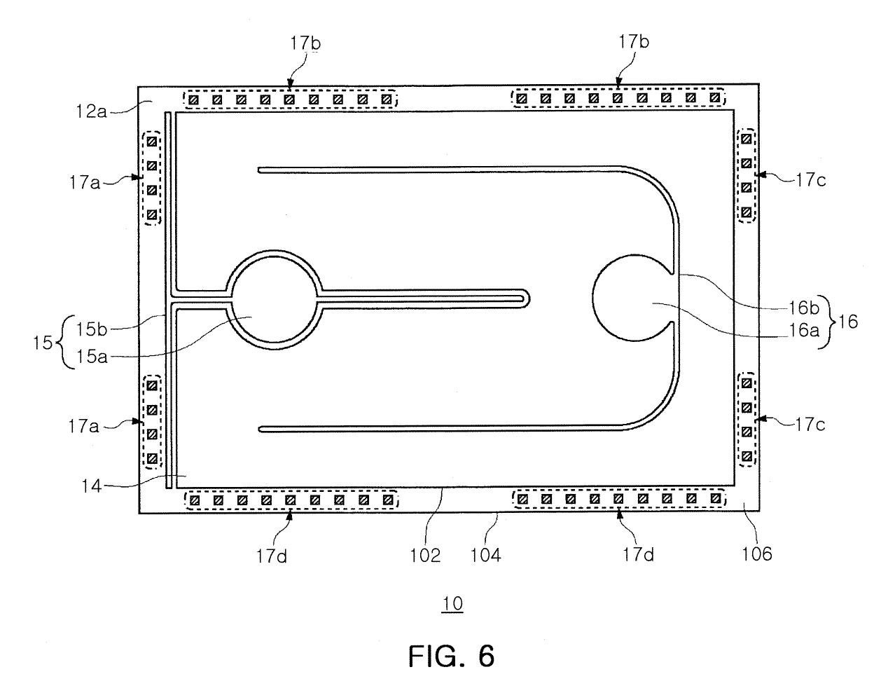

FIG. 6 shows another example of an upper face of the light emitting element 10. In the light emitting element 10 according to the present embodiment, the identification portion 17 is formed on the scribed area 106. The other configuration may be the same as that of the light emitting element described above with reference to FIGS. 1 to 5. Accordingly, the influence of the identification portion 17 on light emission can be prevented. In this manner, the identification portion 17 may be formed on the area (i.e., an inactive area) in which light or current does not pass through.

The light emitting element 10 may have identification portions 17 representing different information on the respective sides of the scribed area 106 formed along the four sides of the outer circumference of the light emitting element 10. For example, the identification portion 17a may represent a lot number, identification portions 17b and 17c may represent reticle coordinates in a wafer, and the identification portion 17d may represent coordinates of the light emitting element 10 in the reticle.

The light emitting element 10 may have a plurality of identification portions 17 representing different information in the scribed area 106 along one side of the outer circumference of the light emitting element 10. When a plurality of identification portions 17 are formed in the scribed area 106 along one side of the outer circumference of the light emitting element 10, identification portions 17 may be formed at both ends of the at least corresponding side. In the present embodiment, the identification portion 17 periodically has concave portions and convex portions having the same shape (a regular square shape in FIG. 6). The identification portions represent identification information by the number, position, pattern, or the like, of the corresponding figure.

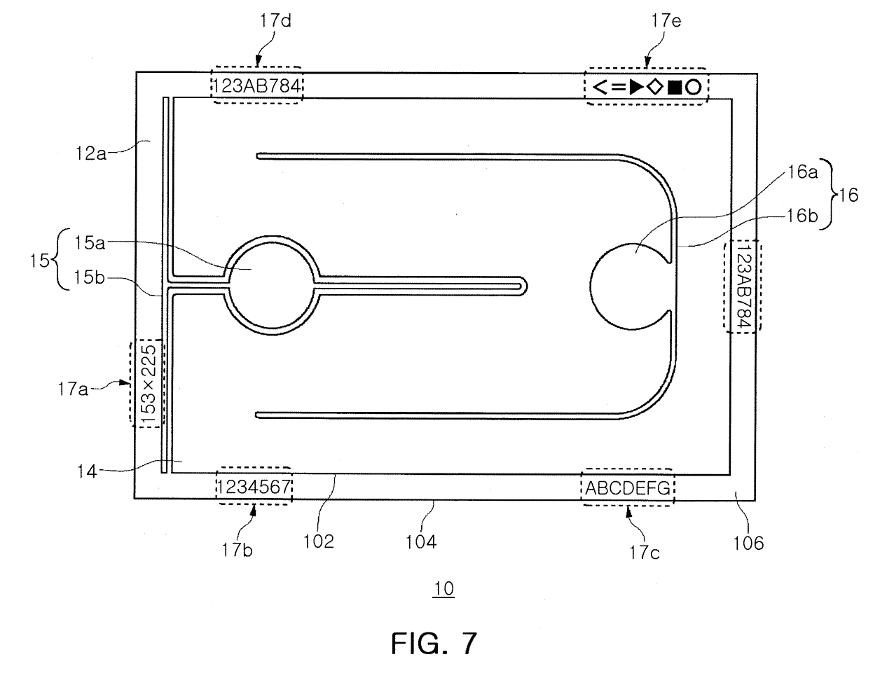

FIG. 7 shows another example of an upper surface of the light emitting element 10. In the example of the light emitting element 10, like the light emitting element 10 illustrated in FIG. 6, identification portions 17 are formed on the scribed area 106. Also, the light emitting element 10 of FIG. 6 has identification portions 17, including identification information in the form of figure, while the light emitting element 10 in this example has identification portions 17 including identification information in the form of character or symbol.

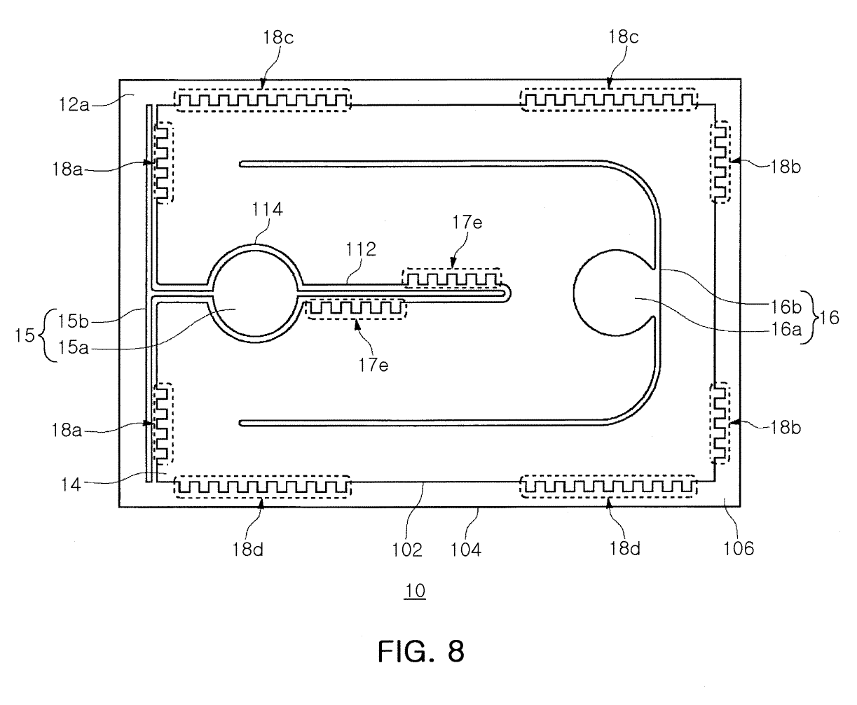

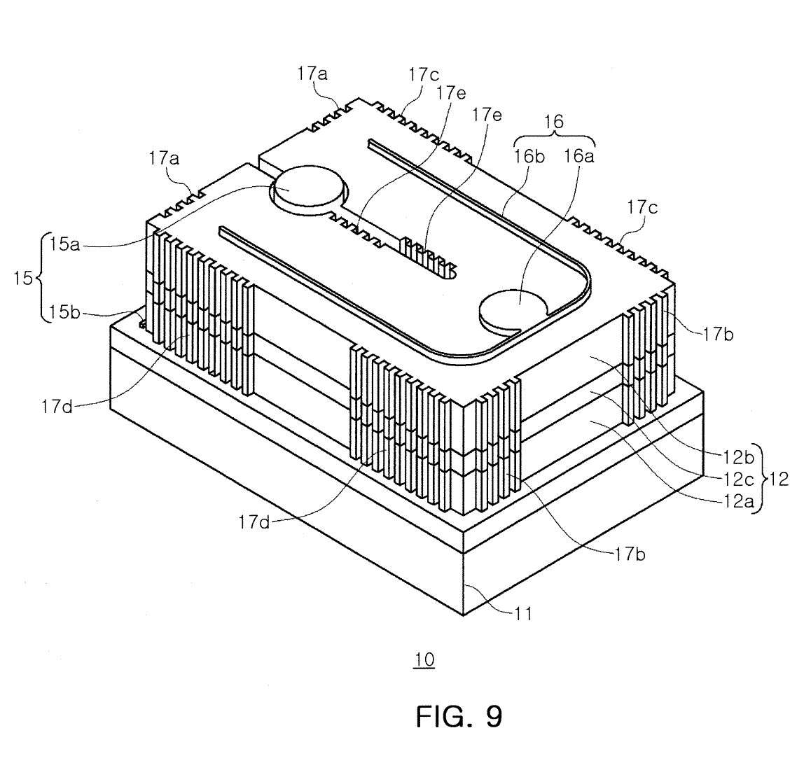

FIG. 8 is another example of an upper face of the light emitting element 10. FIG. 9 is a perspective view of the light emitting element 10 illustrated in FIG. 8. In the light emitting element 10 of this example, the transparent electrode 14, the semiconductor layer 12a, the semiconductor layer 12b, and the active layer 12c have shapes according to information regarding a manufacturing process at a wafer level of the light emitting element 10. The portion having the corresponding shape of the transparent electrode 14 and the semiconductor lamination unit 12 serves as the identification portion 17.

In the light emitting element 10 of this example, the shape of an outer circumference portion of the transparent electrode 14 and the semiconductor lamination unit 12 is formed to allow the light emitting element 10 to be identifiable. Namely, at least one of the transparent electrode 14, the semiconductor layer 12a, the semiconductor layer 12b, and the active layer 12c of each of the light emitting element 10 included in the light emitting element substrate 100 has a shape different from those of other light emitting elements 10.

The identification portion 17, having a concave-convex pattern when viewed from an upper face of the light emitting element 10, may be formed on at least a portion of the outer circumferential portion of the transparent electrode 14 and the semiconductor lamination unit 12. For example, the outer circumferential portion of the transparent electrode 14 and the semiconductor lamination unit 12 has a rectangular shape. And, in at least one side of the transparent electrode 14 and the semiconductor lamination unit 12, the identification portion 17 has a convex portion protruded to the outer side of the corresponding outer circumferential portion or a concave portion protruded to the inner side of the corresponding outer circumferential portion by the number and pattern according to identification information.

The identification portion 17 representing different information may be formed at each side of the transparent electrode 14 and the semiconductor lamination unit 12. Also, two identification portions 17 may be formed on each side of the transparent electrode 14 and the semiconductor lamination unit 12. In this case, a concavo-convex pattern may be formed from both end portions of the respective sides toward the center of the corresponding side on the outer circumference of the transparent electrode 14 and the semiconductor lamination unit 12.

Also, a side according to the stretched area 112 is formed on the transparent electrode 14 and the semiconductor lamination unit 12. The identification portion 17 may be formed on the side of the stretched area 112. In this case, the identification portion 17 may have a concave portion protruded to an inner side of the corresponding side by the number and pattern according to identification information. Also, a facing side is formed on the stretched area 112. The identification portion 17 may be formed on both sides or on one side.

When the identification portion 17 is formed on both sides, identification portions 17 may be formed on positions which are not opposed to each other. For example, one identification portion 17 may be formed from a front end of the stretched area 112 toward the expanded area 114, and the other identification portion 17 may be formed from the expanded area 114 toward the front end of the stretched area 112.

Also, as shown in FIG. 9, the identification portion 17 may be formed across at least two of the semiconductor layer 12a, the active layer 12c, and the semiconductor layer 12b in the lamination direction of the semiconductor lamination unit 12. Namely, the identification portion 17 is formed on the side of the semiconductor layer 12b and the active layer 12c exposed through mesa etching by which the scribed area 106 is formed. A corresponding identification portion 17 may be formed through corresponding mesa etching.

Each of the concave portion and convex portion of the identification portion 17 may be formed to be stretched in a lamination direction. The identification portion 17 may be formed over the transparent electrode 14, the semiconductor layer 12b, and the active layer 12c, or may be formed over the transparent electrode 14, the semiconductor layer 12b, the active layer 12c, and the semiconductor layer 12a. In this case, the outer circumferential portions of the transparent electrode 14, the semiconductor layer 12b, the active layer 12c, and the semiconductor layer 12a have the same shape.

Also, the identification portion 17 may be formed through anisotropic etching in which different masks are used for portions of each of the light emitting elements 10. For example, when a concave portion protruded to the inner side of the boundary line 102 of the scribed area 106 is formed, a common mask pattern may be used, besides a mask pattern defining the boundary line 102 in the manufacturing process of the light emitting element 10.

The mask pattern defining the boundary line 102 may include a first mask having openings of a certain figure at predetermined intervals and a second mask selecting whether to shield each opening of the first mask. Also, the identification portion 17 may be pattern-printed on every light emitting element 10 through electron beam exposure or laser exposure. Also, the shape, size, or the like, of the respective figures of the identification portion 17 may be different. Also, each identification portion 17 may be positioned at intervals greater than those of the figures of the identification portion 17.

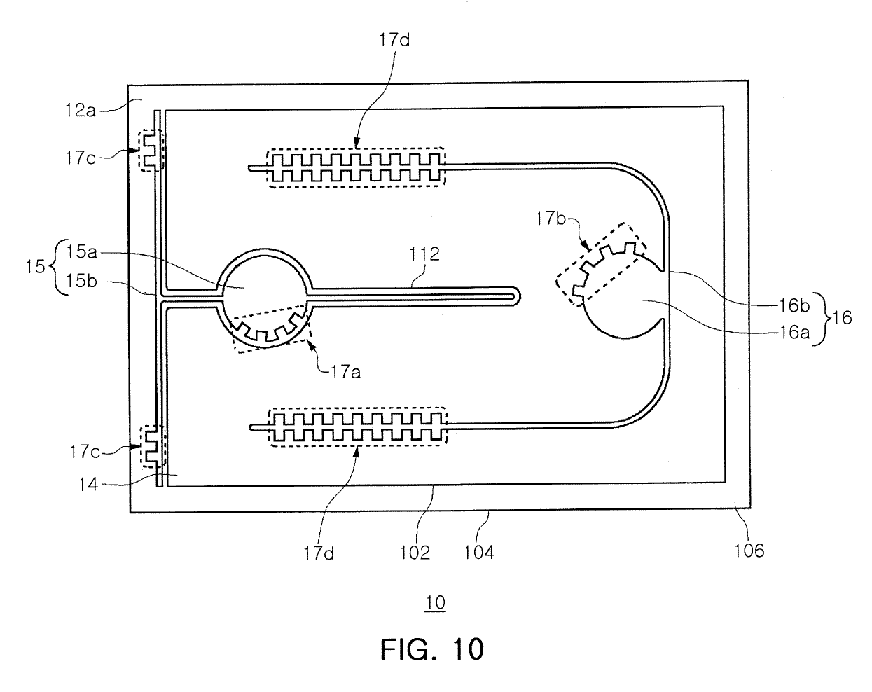

FIG. 10 shows another example of the upper face of the light emitting element 10. In the light emitting element 10 of this example, at least one of the first electrode 15 and the second electrode 16 has a shape according to information regarding a manufacturing process at a wafer level of the light emitting element 10. The portion having the corresponding shape in the first electrode 15 and the second electrode 16 serves as an identification portion 17.

For example, a concave portion is formed on the electrode pad 15a such that it is protruded from an outer circumferential portion of the electrode pad 15a to an inner side when views from the upper face of the light emitting element 10. Also, a concave-convex portion protruded from the outer circumferential portion to the inner side or outer side is formed as the identification portion 17 on the electrode pad 16a. Also, a convex portion protruded toward the outer side of the light emitting element 10 is formed on the elongated electrode unit 15b formed on the scribed area 106.

Also, a convex portion is formed on the elongated electrode unit 16b such that it is protruded toward the outer side of the elongated electrode unit 16b. A convex portion protruded toward the outer side of the light emitting element 10 may be formed on the elongated electrode unit 16b, a convex portion protruded to the inner side of the light emitting element 10 may be formed on the elongated electrode unit 16b, and a convex portion protruded to both sides may be formed on the elongated electrode unit 16b. The convex portion protruded to the outer side of the elongated electrode unit 16b and the convex portion protruded to the outer side of the light emitting element 10 may be formed at different positions of the elongated electrode unit 16b.

Also, a convex portion of the identification portion 17 may be formed in an area of the elongated electrode unit 16b disposed to be parallel to the longer side of the transparent electrode 14. Also, a convex portion of the identification portion may be formed at a position, of the corresponding area, opposed to the elongated electrode unit 15b. Also, the identification portion 17 may be formed on both sides of the elongated electrode unit 16b stretched to both sides of the electrode pad 16a, or may be formed only at one side of the stretched electrode unit 16b. Also, preferably, the identification portion 17 is not formed on the elongated electrode unit 15b formed on the stretched area 112.

In the light emitting element 10 of this example, the first electrode unit 15 and the second electrode unit 16 have a shape allowing the light emitting element 10 to be identifiable. Namely, at least one of the first electrode unit 15 and the second electrode unit 16 of each of the light emitting elements 10 included in the light emitting element substrate 100 has a shape different from those of the other light emitting elements 10.

Also, the first electrode unit 15 and the second electrode unit 16 may be formed through patterning in which different masks are used partially for every light emitting element 10, thereby forming the identification portion 17. Also, the identification portion 17 may be formed only on the stretched electrode units 15b and 16b. Accordingly, the identification portion 17 can be prevented from being covered by a wire bonded to the electrode pads 15a and 16a.

After the pattern of the elongated electrode unit 16b is exposed, the pattern of the identification portion 17 may be exposed to overlap with the pattern of the elongated electrode unit 16b. In this case, as the pattern of the identification portion 17, a pattern having a rectangular shape traversing the elongated electrode unit 16b and arrayed along the stretch direction of the elongated electrode unit 16b may be exposed. Namely, the pattern of the identification portion 17 may be exposed such that a longer side of the rectangular pattern is perpendicular to the elongated electrode unit 16b. Accordingly, even when an exposure position of the pattern of the identification portion 17 is inconsistent, the possibility in which the pattern of the elongated electrode unit 16b and that of the identification portion 17 are separated can be reduced.

Also, the identification portion 17 in this example is made of a conductive material. Accordingly, the identification portion 17 serves as a portion of an electrode. Also, the area of the concavo-convex pattern of the identification portion 17 may be 5% or less of the total area of the first and second electrode units 15 and 16.

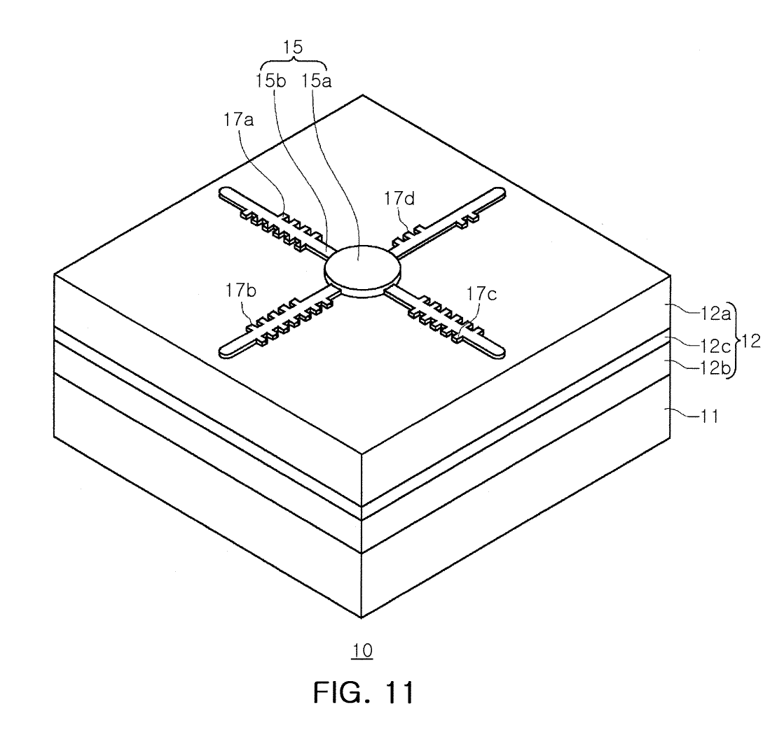

FIG. 11 shows another example of the light emitting element 10. In the light emitting element 10 in this example, the first electrode 15 is formed on the surface of the semiconductor layer 12a. Also, the light emitting element substrate 11 is a conductive substrate. The light emitting element substrate 11 serves as the second electrode 16. Namely, an electrode is formed on a rear face of the semiconductor layer 12b. Here, the first electrode 15 may be formed on the semiconductor layer 12a through a transparent electrode layer.

The electrode pad 15a is formed at the center of the semiconductor layer 12a. Also, the elongated electrode unit 15b is stretched radially from the electrode pad 15a so as to be formed. The identification portion 17 in this example is formed on at least one elongated electrode unit 15b. The shape of the identification portion 17 may be the same as that of the identification portion 17 formed on the elongated electrode unit 16b as described above with reference to FIG. 10.

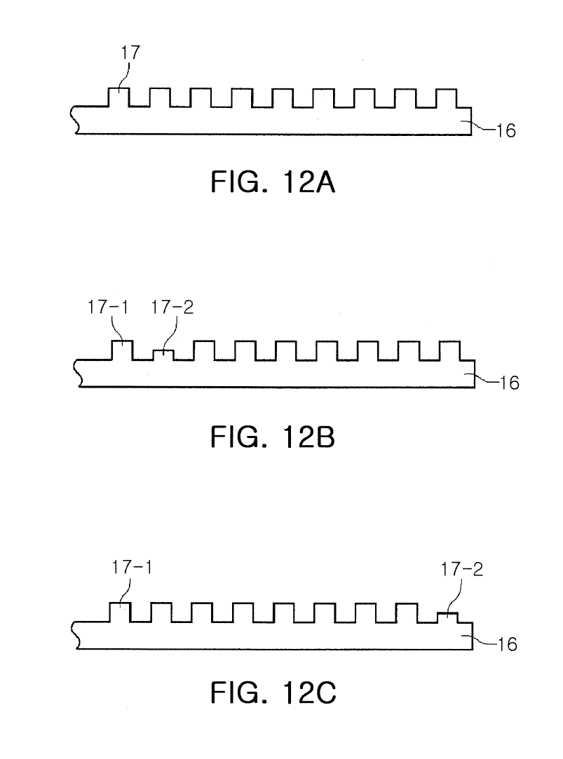

FIGS. 12A to 12C show examples of patterns of the identification portion 17 formed on the elongated electrode unit 16b. As shown in FIGS. 12A to 12C, in each of the light emitting elements 10, the identification portion 17 formed on the elongated electrode unit 16b may have the same number of convex portions. Also, as shown in FIGS. 12B and 12C, the identification portion 17 may have convex portions each having a different length (i.e., length protruded from the elongated electrode unit 16b). The identification portion 17 represents identification information by the array pattern of a first convex portion 171-1 having a first length and a second convex portion 17-2 having a second length. The length of the first convex portion may be double that of the second convex portion.

In this manner, by determining the number of the convex portions of the identification portion 17, rather than following content of identification information, the influence of the patterns of the identification portion 17 on a current diffusion can be reduced. In FIGS. 1 to 11, the vertical type light emitting element 10 is illustrated as an example, but the light emitting element 10 may have a different structure.

Also, in the above example, the identification portion 17 represents identification information by its external appearance, but the identification portion 17 may be an identification element having electrical characteristics according to identification information or may be a memory storing identification information. For example, the identification element may have a resistor having a resistance value different from those of identification elements of other light emitting elements. Also, the memory may have capacitance accumulating the quantity of electric charges different from that of identification elements of other light emitting elements. The electrical charges accumulated in the corresponding quantity may be eliminated through UV irradiation, or the like, after the packaging the light emitting device or before being put on the market. These identification portions may be formed on the scribed area 106.

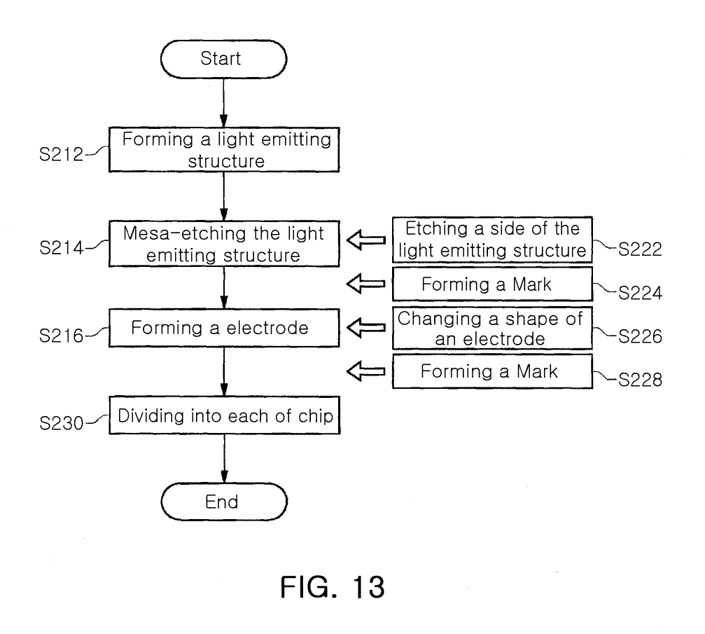

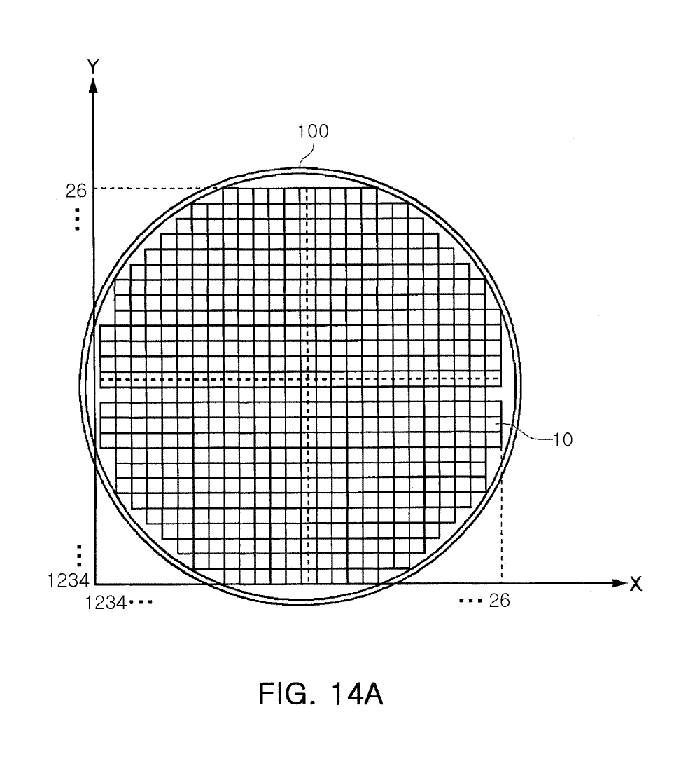

FIG. 13 is a flow chart illustrating a process of a method for manufacturing a light emitting device. First, in a light emitting structure formation operation S212, a light emitting structure is formed on the light emitting element substrate 100. For example, layers having the same configuration as those of the semiconductor lamination unit 12 are formed on the entire surface of the light emitting element substrate 100.

Next, in an etching operation (S214), the scribed area 106 is formed through etching in order to divide the light emitting structure into a plurality of light emitting elements 10. Here, as described above with reference to FIGS. 8 and 9, the identification portion 17 may be formed on the side of the light emitting structure exposed through etching (S222). Also, after the etching operation (S214), as described above with reference to FIGS. 3 to 7, the identification portion 17 having a two-dimensional mark (character, symbol, figure, or the like) may be formed on the scribed area 106 or the transparent electrode 14 (S224).

And then, in an electrode formation operation (S216), the first electrode 15 and the second electrode 16 are formed. Here, as described above with reference to FIGS. 10 to 12C, the identification portion 17 may be formed on at least one of the first electrode 15 and the second electrode 16 (S226). Here, operations S212 to S216 corresponding to the element formation operation (S210) described above with reference to FIG. 1. Also, after the electrode formation operation (S216), as described above with reference to FIGS. 3 to 7, the identification portion 17 having a two-dimensional mark (character, symbol, figure, or the like) may be formed on the scribed area 106 or the transparent electrode 14 (S228).

Thereafter, in a chip separation operation (S230), the light emitting element substrate 11 is divided along the scribed area 106. Accordingly, a plurality of light emitting devices can be manufactured. Also, the operation of forming the identification portion 17 having a two-dimensional mark (character, symbol, figure, or the like) on the scribed area 106 or the transparent electrode 14 (S224) may be performed before the etching operation (S214).

Also, the identification portion 17 may be formed by performing operations S222 to S228. For example, the identification portion 17 representing information such as a manufacturing device, or the like, related to the light emitting structure formation operation (S212) may be formed in operations S222 or S224, and the identification portion 17 representing information such as a manufacturing device, or the like, related to the electrode formation operation (S216) may be formed in operation S226.

Also, with respect to the separated light emitting element 10, a probe of a quality management device is brought into contact with the first electrode 15 and the second electrode 16 to measure electrical and optical characteristics of the light emitting element 10 in a chip state (a first measurement operation). Here, the quality management device identifies the light emitting element 10 based on the external appearance of the identification portion 17 of the light emitting element 10. The quality management device manages the corresponding measurement results by matching the same to the identification information of the light emitting element 10 (a first result storing operation). Whether or not the light emitting element 10 is flawless and the rank of the light emitting element 10 is classified according to the corresponding measurement results.

Then, the light emitting element 10 is disposed within a certain package to form a light emitting device. For example, the package includes a cavity housing the light emitting element 10, a lead frame electrically connected to the first electrode unit 15 and the second electrode unit 16 of the light emitting element 10, and a phosphor material. Further, the package includes a transparent resin encapsulating the light emitting element 10. Optical characteristics of the light emitting device, in which the light emitting element 10 is packaged, are also measured (a second measurement operation). Here, the quality management device observes the identification portion 17 of the light emitting element 10, and manages the measurement results by matching the same to the identification information of the light emitting element 10. The light emitting device is classified by the purpose according to the measurement results.

In this manner, since the identification portion 17 is formed on the light emitting element 10, the measurement results of the electrical and optical characteristics in the chip state or package state obtained after the light emitting element substrate is divided by chip can be matched to the light emitting element 10 so as to be managed. Thus, correlation between the measurement results and the information (a lot number, a position on the wafer, or the like) related to the manufacturing process on the wafer base can be interpreted. Accordingly, the influence of the manufacturing process on the wafer base on the characteristics of the light emitting device in the chip state or package state can be interpreted.

For reference, the electrical characteristics include a driving voltage, a driving current, a forward voltage, or the like, of the light emitting element 10 or the light emitting device. Also, the optical characteristics include a light emission strength and a light emission wavelength of the light emitting element 10 or the light emitting device, a wavelength change according to a change in temperature, color coordinates, color temperature, or the like. In this manner, qualities of each of the light emitting devices can be managed.

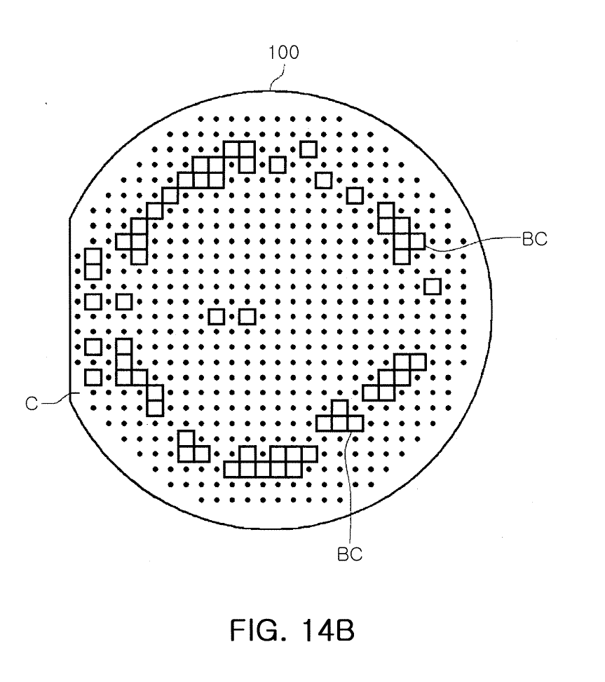

FIG. 14A shows an example of the light emitting element substrate 100. As shown in FIG. 14A, each of the light emitting element 10 of the light emitting element substrate 100 is represented by xy coordinates. In the present example, the quality management device manages each of the light emitting elements 10 by a lot number, a wafer number, and xy coordinates. Each of the light emitting elements 10 includes the identification portion 17 having an external appearance according to a lot number, a wafer number, and xy coordinates of the light emitting element substrate 100.

After each of the light emitting elements 10 is packaged, color coordinates of light emitted from the corresponding package are measured. Here, the external appearance of the identification portion 17 of the light emitting element 10 is observed, and then, the measurement results and the identification information of the light emitting element 10 are matched.

FIG. 14B shows a substrate image corresponding to the light emitting element substrate 100. In the substrate image, an image according to the measurement results of each of the light emitting elements 10 is displayed at positions corresponding to the respective light emitting elements 10. The substrate image may have a mark in a different color, from those of other light emitting elements 10, at a position corresponding to the defective light emitting element 10.

Also, the substrate image shows accumulated measurement results with respect to the light emitting element substrate 100. For example, the substrate image may have a dark mark at a position at which a corresponding light emitting device is determined to be defective with high frequency. Accordingly, in the light emitting element substrate 100, the position of the light emitting element 10 which is highly likely to be defective can be interpreted. For example, in the example of FIG. 14B, it is noted that there are many defective light emitting elements 10 at an upper area and lower area of the light emitting element substrate.

In this manner, when the light emitting device including the light emitting element 10 in a chip state or package state is defective, information regarding a manufacturing process of the wafer base can be traced with respect to the light emitting element 10 disposed in the defective light emitting device. As shown in FIG. 14B, when the distribution of the light emitting elements 10 used in a defective light emitting device is concentrated to certain positions of the light emitting element substrate 100, it may be interfered that the defective light emitting device results from the manufacturing process of the wafer base.

Also, such an interpretation may be also made of measurement results after the light emitting element 10 is mounted in a product such as lighting system, or the like. Production yield of the light emitting device, or the like, can be enhanced by improving the manufacturing process of the wafer base based on the interpretation results.

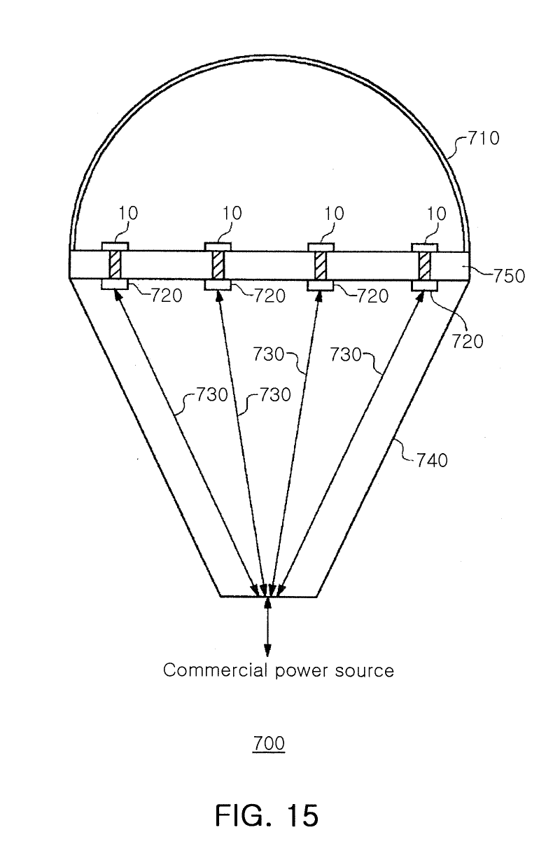

FIG. 15 shows a configuration example of a lighting apparatus 700. The lighting apparatus 700 includes a plurality of light emitting elements 10, a resin cover 710, a plurality of controllers 720, a plurality of power transmission units 730, a support unit 740, and a mounting substrate 750. Each of the light emitting elements 10 may be in a packaged state. For example, the light emitting elements 10 may be loaded on a recess formed on a base substrate and the recess portion may be encapsulated with a resin. The plurality of light emitting elements 10 are mounted on the mounting substrate 750. Also, the controllers 720 for controlling the respective light emitting elements 10 may be fixed to the mounting substrate 750. The controllers 720 and the light emitting elements 10 may be connected by a wire such as a cable, or the like, penetrating the mounting substrate 750.

The resin cover 710 is provided to cover the plurality of light emitting elements 10. The resin cover 710 may have a hemispherical shape. The resin cover 710 may have a hollow shape.

The support unit 740 supports the mounting substrate 750. The support unit 740 may have an opening having a substantially same shape as that of the mounting substrate 750. The mounting substrate 750 is fixed to the corresponding opening. The power transmission unit 730 transmits power for driving the semiconductor light emitting elements 10 to each of the light emitting elements 10. Also, the support 740 is connected to a commercial power source, or the like, and electrically connects the commercial power source and the power transmission unit 730.

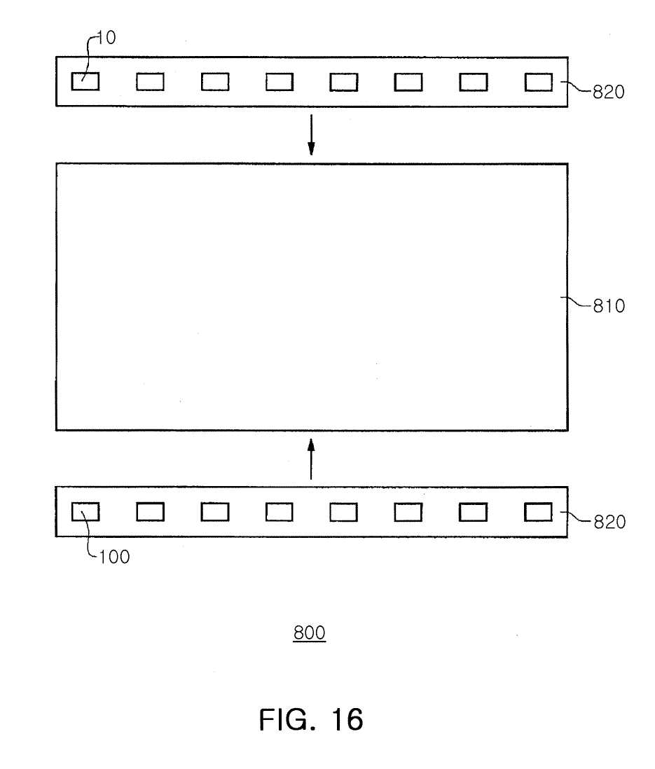

FIG. 16 shows a configuration example of a backlight 800. The back light 800 includes a device array 820 in which a plurality of light emitting elements 10 are arrayed one or two-dimensionally, and a light guide plate 810. Also, the backlight 800 may further include optical sheets such as a diffusion sheet, a lens sheet, or the like, provided at positions facing a light output face of the light guide plate 810.

The device array 820 may be provided to face respective longer sides of the light guide plate 810. Each of the plurality of light emitting elements 10 outputs light from the side of the light guide plate 810 to the interior of the light guide plate 810. The light guide plate 810 outputs incident light from a certain light output face. Also, the device array 810 may be provided to face the opposite side of the light output face of the light guide plate 810. Namely, the backlight 800 may be a direct type backlight. The backlight 800 may be used for a liquid crystal monitor of a television, a liquid crystal screen of a mobile phone, or the like.

Also, the light emitting element 10 described above with reference to FIGS. 1 to 14B can be used for various other purposes. For example, the light emitting element 10 may be used as a light source of a headlight of an automatic two or four-wheeled vehicle. In this case, the headlight may have one or a plurality of light emitting elements 10 and a lens for irradiating light output from the light emitting elements 10 to the outside of the vehicle.

Also, the light emitting element 10 may also be used as a light source of a fluorescent lamp. In this case, the fluorescent lamp may include a plurality of light emitting elements 10 arrayed one-dimensionally and a tube housing the plurality of light emitting elements 10 and irradiating light output from the plurality of light emitting elements 10 to the outside.

Also, the light emitting element 10 may also be used as a pixel of an information display device. In this case, the information display device may include a plurality of light emitting elements 10 arrayed two-dimensionally and a driving circuit driving each of the light emitting elements 10. The plurality of light emitting elements 10 may include a plurality of types of devices, each outputting green light, blue light, and red light.

Also, the light emitting element 10 may also be used as a light source of a signal device. The signal device may include at least two types of light emitting elements 10 each outputting light in a different color and a driving circuit for driving each of the light emitting elements 10. The signal device may have a plurality of light emitting elements 10 for each color.

Also, the light emitting element 10 may also be used as a light source of a pilot light indicating an operation state of an electric device. The pilot light indicates, for example, a power state, or the like, of a television or a notebook computer. The pilot light includes a light emitting element 10 and a driving circuit for driving the light emitting element 10.

As the exemplary embodiments may be implemented in several forms without departing from the characteristics thereof, it should also be understood that the above-described embodiments are not limited by any of the details of the foregoing description, unless otherwise specified, but rather should be construed broadly within its scope as defined in the appended claims. Therefore, various changes and modifications that fall within the scope of the claims, or equivalents of such scope are therefore intended to be embraced by the appended claims.

An order of execution of processing such as operations, procedures, undertakings, or the like, in the apparatus, system, program and method disclosed or illustrated in claims, specification, and drawing may be arbitrary unless otherwise specified such as, particularly, ‘ahead’, ‘before’, or the like, or unless an output of previous processing is used in a follow-up processing. It should be understood that, although description is made by using ‘first’, ‘next’, or the like, for the sake of convenience, in relation to an operational flow of claims, specification, and drawings, it does not mean that the operations must be necessarily performed in the foregoing order.

What is claimed is:

1. A method for manufacturing a light emitting device, the method comprising:
forming a plurality of light emitting elements on a light emitting element substrate;
forming an identification portion on each of the light emitting elements to allow a pertinent light emitting element to be distinguishable from other light emitting elements; and
separating the light emitting elements to form a plurality of light emitting devices.

2. The method of claim 1, wherein the identification portion has an external appearance allowing each of the light emitting elements to be distinguishable from the other light emitting elements.

3. The method of claim 2, wherein each of the light emitting elements comprises:
a first conductive type semiconductor layer;
a second conductive type semiconductor layer;
a active layer formed between the first conductive type semiconductor layer and the second conductive type semiconductor layer;
a first electrode unit electrically connected to the first conductive type semiconductor layer; and
a second electrode unit electrically connected to the second conductive type semiconductor layer,
wherein, in the identification portion formation operation, the identification portion is formed on at least one of the first conductive type semiconductor layer, the second conductive type semiconductor layer, the active layer, the first electrode unit, and the second electrode unit.

4. The method of claim 3, wherein the first electrode unit comprises a transparent electrode formed on the first conductive type semiconductor layer, and in the identification portion formation operation, the identification portion is formed on the transparent electrode.

5. The method of claim 3, wherein the first electrode unit comprises a transparent electrode formed on the first conductive type semiconductor layer, and in the identification portion formation operation, the identification portion is formed on the first conductive type semiconductor layer, and thereafter, in the element formation operation, the transparent electrode is formed on the first conductive type semiconductor layer.

6. The method of claim 3, wherein the second electrode unit is formed on an exposed area of the second conductive type semiconductor layer which is exposed as portions of the first conductive type semiconductor layer and the active layer are removed, and
in the identification portion formation operation, the identification portion is formed on the exposed area.

7. The method of claim 3, wherein at least one of the first and second electrode units is formed to have a shape allowing the pertinent light emitting element identifiable, thus forming the identification portion.

8. The method of claim 7, wherein at least one of the first and second electrode units has a shape according to the position on the light emitting element substrate, thus forming the identification portion.

9. The method of claim 7, wherein at least one of the first and second electrode units comprises;
an electrode pad; and
an elongated electrode unit having a width smaller than that of the electrode pad and stretched from the electrode pad so as to be formed,
wherein the elongated electrode unit is formed to have a shape allowing the light emitting element to be identifiable.

10. The method of claim 7, wherein the plurality of light emitting elements are formed such that at least one of the first and second electrode units have a shape different from those of the other light emitting elements.

11. The method of claim 3, wherein the second electrode unit is formed on an exposed area of the second conductive type semiconductor layer which is exposed as portions of the first conductive type semiconductor layer and the active layer are removed, and
in the identification portion formation operation, the identification portion is formed on the side of the first conductive type semiconductor layer and the active layer exposed as portions of the first conductive type semiconductor layer and the active layer are removed.

12. The method of claim 3, wherein at least one of the first conductive type semiconductor layer, the second conductive type semiconductor layer, and the active layer is formed to have a shape allowing the pertinent light emitting element to be identifiable, thus forming the identification portion.

13. The method of claim 12, wherein the identification portion is formed over at least two of the first conductive type semiconductor layer, the second conductive type semiconductor layer, and the active layer in a lamination direction of the first conductive type semiconductor layer, the second conductive type semiconductor layer, and the active layer.

14. The method of claim 12, wherein at least one of the first conductive type semiconductor layer, the second conductive type semiconductor layer, and the active layer has a shape different from those of the other light emitting elements.

15. The method of claim 1, wherein the identification portion is formed on a face of a light output side of the light emitting element.

16. A light emitting device comprising:
an element substrate;
a light emitting element provided on the element substrate; and
an identification portion allowing a pertinent light emitting element to be distinguishable from other light emitting elements.

17. The device of claim 16, wherein the identification portion has an external appearance allowing each of the light emitting elements to be distinguishable from the other light emitting elements.

18. The device of claim 17, wherein each of the light emitting elements comprises:
a first conductive type semiconductor layer;
a second conductive type semiconductor layer;
a active layer formed between the first conductive type semiconductor layer and the second conductive type semiconductor layer;
a first electrode unit electrically connected to the first conductive type semiconductor layer; and
a second electrode unit electrically connected to the second conductive type semiconductor layer,
wherein the identification portion is formed on at least one of the first conductive type semiconductor layer, the second conductive type semiconductor layer, the active layer, the first electrode unit, and the second electrode unit.

19. The device of claim 18, wherein the first electrode unit comprises a transparent electrode formed on the first conductive type semiconductor layer, and the identification portion is formed on the transparent electrode.

20. The device of claim 18, wherein the first electrode unit comprises a transparent electrode formed on the first conductive type semiconductor layer covered by the transparent electrode.

21. The device of claim 18, wherein at least one of the first and second electrode units has a shape distinguishable from the pertinent light emitting element from other light emitting elements, thus serving as the identification portion.

22. The device of claim 21, wherein at least one of the first and second electrode units comprises;
an electrode pad; and
an elongated electrode unit having a width smaller than that of the electrode pad and stretched from the electrode pad so as to be formed,
wherein the elongated electrode unit has a shape allowing the pertinent light emitting element to be identifiable, thus serving as the identification portion.

23. The device of claim 21, wherein the second electrode unit is formed on an exposed area of the second conductive type semiconductor layer which is exposed as portions of the first conductive type semiconductor layer and the active layer are removed, and
the identification portion is formed on the side of the first conductive type semiconductor layer and the active layer exposed as portions of the first conductive type semiconductor layer and the active layer are removed.

24. The device of claim 18, wherein at least one of the first conductive type semiconductor layer, the second conductive type semiconductor layer, and the active layer has a shape allowing the pertinent light emitting element to be identifiable, thus serving as the identification portion.

25. The device of claim 24, wherein, in a lamination direction of the first conductive type semiconductor layer, the second conductive type semiconductor layer, and the active layer, at least two of the first conductive type semiconductor layer, the second conductive type semiconductor layer, and the active layer have the same shape, thus serving as the identification portion.

26. A light emitting element substrate including a plurality of light emitting elements formed thereon, the substrate comprising an identification portion allowing a pertinent light emitting element to be distinguishable from other light emitting elements.

27. The substrate of claim 26, wherein the identification portion has an external appearance allowing each of the light emitting elements to be distinguishable from the other light emitting elements.

28. The substrate of claim 27, wherein each of the light emitting elements comprises:
a first conductive type semiconductor layer;
a second conductive type semiconductor layer;
a active layer formed between the first conductive type semiconductor layer and the second conductive type semiconductor layer;
a first electrode unit electrically connected to the first conductive type semiconductor layer; and
a second electrode unit electrically connected to the second conductive type semiconductor layer,
wherein, the identification portion is formed on at least one of the first conductive type semiconductor layer, the second conductive type semiconductor layer, the active layer, the first electrode unit, and the second electrode unit.

29. The substrate of claim 28, wherein the shape of at least one of the first conductive type semiconductor layer, the second conductive type semiconductor layer, the active layer, the first electrode unit, and the second electrode unit of each of the plurality of light emitting elements is different from those of other light emitting elements.

30. A quality management method for managing the quality of a plurality of light emitting elements formed on a light emitting element substrate recited in claim 26, the method comprising:
measuring the characteristics of each of the plurality of light emitting elements; and
identifying each of the plurality of light emitting elements and storing the measurement results of the characteristics of each of the plurality of light emitting elements, based on an identification portion of each of the plurality of light emitting elements.

31. The method of claim 30, wherein, in the step of measuring the characteristics, the light emitting element substrate is divided into light emitting elements, and the characteristics of each of the light emitting elements are measured after packaging.
